(19) United States
(12) Patent Application Publication
(10) Pub. No.: US 2020/0043562 A1
(43) Pub. Date: Feb. 6, 2020

(54) METHOD FOR PROGRAMMING A ONE-TIME PROGRAMMABLE STRUCTURE, SEMICONDUCTOR COMPONENT AND RADIO FREQUENCY COMPONENT

(71) Applicant: Infineon Technologies AG, Neubiberg (DE)

(72) Inventors: Wolfgang LIEBL, Bad Abbach (DE); Stefan ALMSTAETTER, Geisenfeld (DE); Jens ARKENAU, Regensburg (DE); Josef BOECK, Putzbrunn (DE); Rainer LEUSCHNER, Regensburg (DE); Gunther MACKH, Neumarkt (DE)

(21) Appl. No.: 16/527,619

(22) Filed: Jul. 31, 2019

(30) Foreign Application Priority Data
Aug. 1, 2018 (DE) 102018118724.6

(51) Int. Cl. G11C 17/10; H03B 5/02; G11C 17/14; H01L 23/525; H01L 21/3213

(52) U.S. Cl. CPC G11C 17/10; H03B 5/02; H04B 1/16; H01L 23/5258; H01L 21/32133; G11C 17/143

(57) ABSTRACT

A method for programming a one-time programmable structure is disclosed. The method comprises producing an electrical circuit having the one-time programmable structure. The method furthermore comprises severing the one-time programmable structure by etching the one-time programmable structure in a separating region.

### CROSS REFERENCE TO RELATED APPLICATIONS

This application claims priority under 35 U.S.C. § 119 to German Patent Application No. 102018118724.6 filed on Aug. 1, 2018, the contents of which are incorporated by reference herein in their entirety.

### TECHNICAL FIELD

Example implementations are concerned with a method for programming a one-time programmable structure. Further example implementations relate to a semiconductor component and to a radio-frequency component.

### BACKGROUND

Electrical circuits in semiconductor components can comprise fuses or fuse structures, which can be severed for instance for the purpose of setting properties of the electrical circuit. Such fuse structures can be referred to as one-time programmable structures since the properties of the electrical circuit change, for example, in the case of severing.

It is possible to destroy one-time programmable structures using an electrical pulse or a laser pulse in partial regions in order to sever the one-time programmable structures. With the use of laser pulses or laser radiation, however, it may be possible that not only the envisaged partial regions of the one-time programmable structures but also further regions of the semiconductor component or of the electrical circuit are damaged, as a result of which a functionality of the semiconductor component or of the electrical circuit can be restricted. Furthermore, a thickness of useable one-time programmable structures that are severed using a laser beam can be limited on account of limited laser power.

### SUMMARY

Therefore, there may be a need for improved concepts for programming one-time programmable structures.

This need can be met by the subject matter of the claims.

Some examples relate to a method for programming a one-time programmable structure. The method comprises producing an electrical circuit having the one-time programmable structure. The method furthermore comprises severing the one-time programmable structure by etching the one-time programmable structure in a separating region.

Further examples relate to a semiconductor component comprising an electrical circuit. The semiconductor component furthermore comprises a severed one-time programmable structure of the electrical circuit. In this case, a separating surface of the one-time programmable structure is an etched surface.

A further example relates to a radio-frequency component or RF component. The radio-frequency component comprises a semiconductor component having an electrical circuit having an oscillator circuit. The oscillator circuit is designed to generate an oscillator signal having a frequency that is set at least by a severed one-time programmable structure of the semiconductor component. The radio-frequency component is designed to emit a radio-frequency signal on the basis of the oscillator signal.

### BRIEF DESCRIPTION OF THE FIGURES

Some examples of devices and/or methods are explained in greater detail merely by way of example below with reference to the accompanying figures, in which:

FIG. 1 shows a flow diagram of a method for programming a one-time programmable structure;

FIG. 2 shows a schematic plan view of a semiconductor component having a severed one-time programmable structure;

FIG. 3 shows a schematic plan view of a radio-frequency component for emitting a radio-frequency signal;

FIG. 4 shows a schematic plan view of one-time programmable structures that are severed using laser radiation;

FIG. 5 shows a schematic plan view of one-time programmable structures that are severed using etching; and

FIGS. 6A-6E show a schematic illustration of a method for severing a one-time programmable structure using etching processes.

### DESCRIPTION

Various examples will now be described more thoroughly with reference to the accompanying figures, in which examples are illustrated. In the figures, the thicknesses of lines, layers and/or regions may be exaggerated for elucidation purposes.

While further examples are suitable for various modifications and alternative forms, some specific examples thereof are accordingly shown in the figures and described thoroughly below. However, this detailed description does not limit further examples to the specific forms described. Further examples can cover all modifications, counterparts and alternatives that fall within the scope of the disclosure. Throughout the description of the figures, identical or similar reference signs refer to identical or similar elements which can be implemented identically or in modified form in a comparison with one another, while they provide the same or a similar function.

It goes without saying that if one element is designated as “connected” or “coupled” to another element, the elements can be connected or coupled directly or via one or more intermediate elements. If two elements A and B are combined using an “or”, this should be understood such that all possible combinations are disclosed, i.e. only A, only B, and A and B, unless explicitly or implicitly defined otherwise. An alternative wording for the same combinations is “at least one from A and B” or “A and/or B”. The same applies, mutatis mutandis, to combinations of more than two elements.

The terminology used here for describing specific examples is not intended to be limiting for further examples. If a singular form, e.g. “a, an” and “the”, is used and the use of only a single element is defined neither explicitly nor implicitly as obligatory, further examples can also use plural elements in order to implement the same function. If a function is described below as being implemented using a plurality of elements, further examples can implement the same function using a single element or a single processing entity. Furthermore, it goes without saying that the terms “comprises”, “comprising”, “has” and/or “having” in their usage indicate with greater precision the presence of the specified features, integers, steps, operations, processes, elements, components and/or a group thereof, but do not exclude the presence or the addition of one or more other features, integers, steps, operations, processes, elements, components and/or a group thereof.

Unless defined otherwise, all terms (including technical and scientific terms) are used here in their customary meaning in the field with which examples are associated.

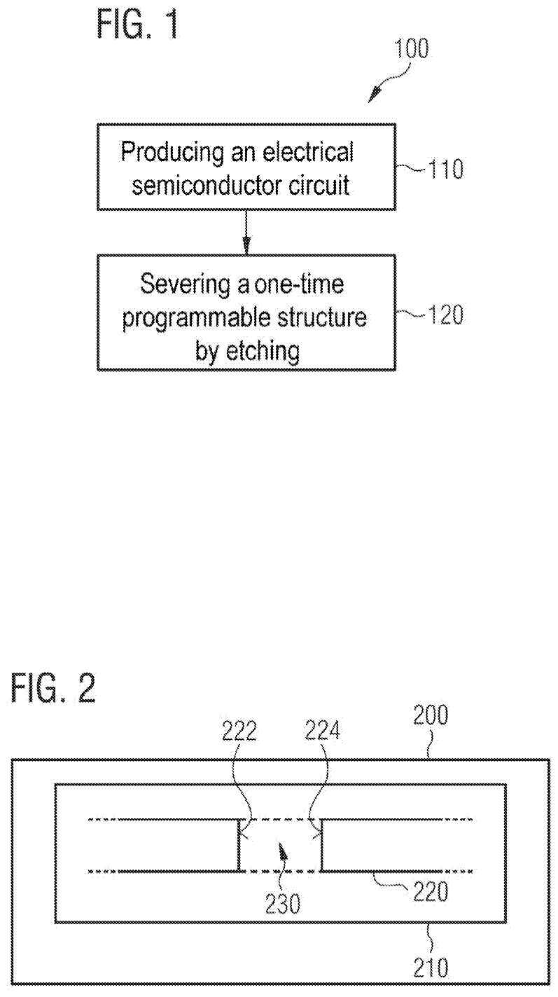

FIG. 1 shows a flow diagram of a method 100 for programming a one-time programmable structure. The method 100 comprises producing 110 an electrical circuit having the one-time programmable structure. The method 100 furthermore comprises severing 120 the one-time programmable structure by etching the one-time programmable structure in a separating region of the one-time programmable structure.

Severing 120 one-time programmable structures in semiconductor components using etching can provide, for example, an alternative to severing one-time programmable structures using a laser pulse. With the use of etching for severing 120 the one-time programmable structures, it is possible, for example, to minimize a risk of damage to structures in surroundings of the separating region of the one-time programmable structure. As a result, for instance, a layout of the electrical circuit can be made more flexible or simpler. Furthermore, the severing 120 using etching can reduce for example limitations regarding the width and/or thickness of the one-time programmable structures. After the severing 120, a passivation can be applied directly on the severed one-time programmable structures, since, in contrast to severing using laser beams, for example, no impurities (for example deposits or spatter residues) arise in the region of the separating location during the separating process using etching.

The one-time programmable structure can be for example an electrically conductive structure of a semiconductor component that can be severed using one etching process or a plurality of etching processes. Severing 120 the one-time programmable structure can be referred to as programming the one-time programmable structure since, as a result, an electrical state of the one-time programmable structure can change in a binary fashion, for instance from electrically conducting to electrically insulating. By way of example, a plurality of one-time programmable structures can be programmed or severed using the method. The one-time programmable structure can be programmed for example exclusively once, e.g. in contrast to reprogrammable memories such as DRAM, SRAM or Flash memories. Part of the one-time programmable structure can be destroyed during programming.

The electrical circuit can be produced 110 on a semiconductor substrate of a semiconductor component or semiconductor device. The electrical circuit can be an integrated circuit. The one-time programmable structure or fuse structure can be formed for example by an electrically conductive structure or conductor track, for instance a metallic conductor track. The one-time programmable structure can be part of a structured metal layer of the semiconductor component. The electrical circuit can be produced 110 for example with a multiplicity of one-time programmable structures. The plurality of one-time programmable structures can be arranged alongside one another in a common lateral plane of the semiconductor component, for example in a metal layer of the semiconductor component that is situated closest to a surface of the semiconductor component. Before the severing 120, the one-time programmable structure can form for instance an electrical contact between an input and an output of the one-time programmable structure. By way of example, before the process of severing 120 the one-time programmable structure, in the separating region of the one-time programmable structure, electrically conductive material can be provided.

By etching the separating region for the purpose of severing 120 the one-time programmable structure, it is possible to remove the electrically conductive material within the separating region, thereby achieving an electrical isolation between the input and the output of the one-time programmable structure. In other words, an electrical through contact of the one-time programmable structure can be separated by severing 120 the one-time programmable structure. By way of example, a plurality of predetermined one-time programmable structures of a multiplicity of one-time programmable structures of the electrical circuit can be severed 120 in an etching process. The one-time programmable structure can be connected to a circuit, which can comprise active circuit elements (transistors), for example, or to a circuit part, in order to set specific characteristics of the circuit depending on whether or not the programmable structure has been severed.

For example, the method 100 can furthermore comprise producing an etching mask. The etching mask can be produced for example after producing 110 the one-time programmable structure. The etching mask can have an opening above the separating region of the one-time programmable structure. By way of example, the electrical circuit of the semiconductor component can comprise a multiplicity of one-time programmable structures and the etching mask can have openings above separating regions of a plurality of selected or predetermined one-time programmable structures. As a result, it is possible, for example, to sever the selected one-time programmable structures in a common etching process and, as a result, to carry out the severing 120 more efficiently.

For example, the etching mask can be produced using a maskless lithography method. For example, LDI (LDI: Laser Direct Imaging) or electron beam lithography can be used as maskless lithography methods. In LDI, for example, structures of the etching mask can be exposed and developed using a controlled laser sequentially into a resist layer (e.g. photoresist or lithography mask) in order to produce the etching mask. Maskless lithography methods make it possible to produce the openings of the etching mask for example accurately above the separating regions of the one-time programmable structures to be severed. Alternatively, an etching mask can be printed onto the semiconductor component, for instance, such that an opening is provided above the separating region of the one-time programmable structure to be severed. Applying the etching mask by printing makes it possible for example to dispense with exposing and/or developing the etching mask.

By way of example, the etching mask is formed in such a way that an extent of the opening of the etching mask in the direction of a width of the one-time programmable structure is greater than a width of the one-time programmable structure. This makes it possible to ensure that the one-time programmable structure is completely severed 120 in a subsequent etching process. The etching mask can be produced for example with a resolution more accurate than 4 μm and/or with an overlay offset of less than 1 μm. The high accuracy when producing the etching mask makes it possible for instance to reduce an overlap of the openings of the etching mask above the separating region of the one-time programmable structures.

By way of example, wet-chemical etching can be used for severing 120 the one-time programmable structure, for instance by etching liquid being applied on the etching mask produced before severing the one-time programmable structure. Alternatively or additionally, by way of example, a dry-chemical etching process can be used for severing 120 the one-time programmable structure.

By way of example, the etching for severing 120 the one-time programmable structure can comprise selectively applying an etching liquid above the separating region of the one-time programmable structure in a maskless fashion. Etching liquid can be applied, for example, in a defined manner locally in the separating region or above the separating region of the one-time programmable structure, for example using a printing method. This makes it possible for instance to dispense with producing an etching mask.

For example, the one-time programmable structure can have a thickness of at least 0.7 μm (or of at least 1 μm) within the separating region before the etching. Since the one-time programmable structure is severed 120 using etching, it is possible to use even thicker one-time programmable structures, which could not be severed using laser beams for example when employing prior laser severing on account of limited laser energies. As a result, it may be possible to provide the one-time programmable structure for example in the same metal layer that also comprises a pad metallization of the electrical circuit of the semiconductor component. The higher thickness of the one-time programmable structures makes possible, for example, a reduced electrical resistance of one-time programmable structures of the electrical circuit which remain unsevered on account of the programming of the one-time programmable structures.

For example, the one-time programmable structure can have a width of at least 0.5 μm (or of at least 1 μm, of at least 2 μm or of at least 5 μm) and/or of less than 50 μm (or of less than 30 μm, or of less than 10 μm) within the separating region before the etching. As a result of the severing 120 using etching, a width of the one-time programmable structure can be chosen freely since, for severing wider separating regions, for example, etching masks having larger openings can be produced and, consequently, there are for example no limitations of the width of the structures to be severed.

By way of example, the method 100 can furthermore comprise etching a passivation layer or isolation layer arranged above the one-time programmable structure. By etching the passivation layer, for example an inorganic passivation layer, it is possible for the one-time programmable structure to be exposed for the severing. For example, the one-time programmable structure can be covered by the passivation layer before the severing 120. The passivation layer can be removed in a first etching process, for example, in order to expose the separating region of the one-time programmable structure. The one-time programmable structure can thereupon be severed in a second etching process. By way of example, different etching processes are used on account of the different material properties of the passivation layer and of the one-time programmable structure.

For example, an isolation layer or passivation layer can be applied after the etching at least in the region of the separating region of the severed one-time programmable structure. The isolation layer can be applied for example over the whole area on the semiconductor component, for example as a closed or continuous layer. The isolation layer can be applied in particular in a manner adjoining the ends of the separating region of the severed one-time programmable structure, for example also on the etching surfaces of the severed one-time programmable structure. By way of example, an imide layer can be applied as the isolation layer. By virtue of the fact that the one-time programmable structure has been severed using an etching process, a surface of the separating region can be smooth or free of unevennesses, for example free of spatter residues. As a result, it is possible, for example, to apply an isolation layer also in the severed region of the one-time programmable structure.

The method 100 can comprise for example measuring one or more electrical parameters of the electrical circuit before severing the one-time programmable structure. The electrical parameter can be an inductance value of an inductance of the electrical circuit. The electrical parameter can be altered, for example, using severing one or more one-time programmable structures of the electrical circuit, for example in order to finely set or trim the electrical parameter. For example, an electrical property of the electrical circuit can thus be altered by severing 120 the one-time programmable structure. The electrical property can for example alternatively or additionally be a value of a capacitance and/or a value of an electrical resistance of the electrical circuit.

By way of example, on the basis of the measured electrical parameter and a target parameter to be set, for example a setpoint value of the electrical property of the electrical circuit, it is possible to ascertain which of the one-time programmable structures of the electrical circuit is to be severed in order to achieve the target parameter. In other words, on the basis of the measurement, it is possible to effect a selection of the one-time programmable structures to be severed, wherein a corresponding etching mask can be created for example on the basis of the selection. For example, the electrical circuit can comprise a plurality of one-time programmable structures and, using the etching mask, at least one of the one-time programmable structures of the plurality of one-time programmable structures can be separated on the basis of the measured parameter.

By way of example, a readable chip identification number of the electrical circuit or of the semiconductor component can be altered by severing the one-time programmable structure. By severing individual one-time programmable structures, it is possible to create a binary code, for example, which can be read out by the electrical circuit. As a result, it is possible to impress an individual chip identification number on the semiconductor component.

The electrical circuit can be arranged for example at a front side of a semiconductor substrate of the semiconductor component. The front side of the semiconductor substrate can be used, for example, to implement more complex structures than at a rear side of the semiconductor substrate, since process parameters (for example temperature) and handling may be limited for the rear side, for example if structures have already been produced at a side of the semiconductor substrate.

The electrical circuit can comprise a plurality of structured, lateral metal layers of the semiconductor component, for example, which can be contacted through vertical connections (vias). The one-time programmable structures can be arranged for example in a topmost metal layer situated closest to the front side of the semiconductor substrate. For example, it is possible to measure a vertical direction orthogonally to a surface of the front side of the semiconductor substrate and to measure a lateral direction parallel to the surface of the front side of the semiconductor substrate.

A method for producing a semiconductor component can comprise for example a method for programming a one-time programmable structure as described e.g. in association with FIG. 1.

The semiconductor component having the electrical circuit can be for example a processor, a memory component, a microcontroller, a transmitter, a receiver or a radio-frequency component.

FIG. 2 shows a schematic plan view of a semiconductor component 200 comprising a severed one-time programmable structure 220. The semiconductor component 200 can comprise an electrical circuit 210 having the severed one-time programmable structure 220. A separating surface 222, 224 of the one-time programmable structure can be an etched surface. The one-time programmable structure 220 can be severed using etching, for example, such that the surfaces of the one-time programmable structure that face a separating region of the one-time programmable structure are etching surfaces.

The one-time programmable structure 220 can be formed by an electrically conductive line or metal line, for example, which is interrupted by a separating region. By way of example, a first region of the severed one-time programmable structure 220, said first region having the separating surface 222, can be separated from a second region of the severed one-time programmable structure 220, said second region having the separating surface 224, by a separating region 230. The separating region 230 can provide for example an isolation of the severed one-time programmable structure 220, such that the severed one-time programmable structure 220 forms an electrical open circuit.

By way of example, an insulating layer arranged below the one-time programmable structure 220 has a trench or a mesa in an etched separating region of the one-time programmable structure. The one-time programmable structure can be arranged directly on the insulating layer, for example. The trench or the mesa may have arisen for example on account of an overetching or underetching of isolation layers alongside the one-time programmable structure when etching through the one-time programmable structure. The insulating layer can have a stepped contour, for example, in a region below the separating region of the severed electrical fuse structure at boundaries of the separating region.

By way of example, the semiconductor component 200 can furthermore comprise an isolation layer arranged at least in a separating region of the one-time programmable structure. The isolation layer can be formed by an imide layer, for example. It may be possible for the isolation layer to adhere fixedly to the severed one-time programmable structure in the separating region, since, on account of the etching method used, around the separating region, it is possible to achieve a planar surface having a sufficient adhesion coefficient with respect to the isolation layer. By way of example, a continuous or complete isolation at the surface of the semiconductor component 200 is provided as a result of the isolation layer or imide layer also in the separating region of the severed one-time programmable structure.

By way of example, at least one part of the electrical circuit 210 is arranged vertically between the one-time programmable structure and a semiconductor substrate of the semiconductor component. It is possible for the part of the electrical circuit 210 to be arranged directly below an isolation layer arranged below the severed one-time programmable structure 220, for example in a metal layer that is closest to the one-time programmable structure. The arrangement of parts of the electrical circuit also below the one-time programmable structure can for example reduce a size of the semiconductor component or simplify a layout of the electrical circuit.

By way of example, the electrical circuit of the semiconductor component 200 is designed to detect whether the one-time programmable structure is severed. The semiconductor component 200 can comprise for instance a multiplicity of one-time programmable structures, only a portion of which may be severed. As a result of severing individual programmable structures, it is possible to provide identification information of the semiconductor component, for example, which can be read out by the electrical circuit 210. Detecting whether or not the one-time programmable structure is severed can furthermore make it possible to verify or to check whether the one-time programmable structure has been successfully severed completely by the etching process.

By way of example, the electrical circuit 210 comprises an oscillator circuit. The oscillator circuit can be designed to generate an oscillator signal having a frequency that is set at least by the severed one-time programmable structure. As a result of severing the one-time programmable structure, it is possible to set a value of an inductance of the oscillator circuit, for instance, which influences the frequency. By way of example, an electrical circuit of the oscillator circuit can comprise a plurality of one-time programmable structures, of which selected one-time programmable structures are severed for the fine setting of a frequency-influencing inductance value of the electrical structure.

Further details and aspects are described in connection with examples explained further above or further below. The examples shown in FIG. 2 can have one or more optional, additional features corresponding to one or more aspects described further above or further below in connection with the proposed concept or one or more examples (for example in connection with FIG. 1 or FIGS. 3 to 6E).

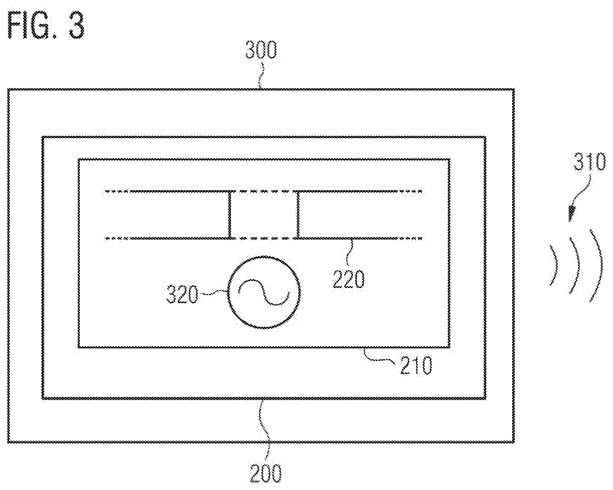

FIG. 3 shows a schematic plan view of a radio-frequency component 300 for emitting a radio-frequency signal 310. The radio-frequency component 300 comprises for example a semiconductor component 200 having an oscillator circuit designed to generate an oscillator signal 320. The radio-frequency component 300 can be designed to emit a radio-frequency signal 310 on the basis of the oscillator signal 320.

The radio-frequency component 300 can be used for communication applications, for example. The radio-frequency component 300 can be a radar sensor and a frequency of a radar signal of the radar sensor can be based on the oscillator circuit, for example. The semiconductor component can comprise one or more one-time programmable structures, some of which may be severed. The severed one-time programmable structures can influence the oscillator circuit and a frequency of the oscillator signal and be severed for the fine setting of the oscillator signal, for instance. The fine setting of the oscillator circuit and thus of the oscillator signal 320 makes it possible to carry out fine setting of the frequency of the radar signal, for instance. The frequency of the radar signal can lie for instance in an interval of between 20 GHz and 100 GHz, in particular between 76 GHz and 81 GHz.

Further details and aspects are described in connection with examples explained further above or further below. The examples shown in FIG. 3 can have one or more optional, additional features corresponding to one or more aspects described further above or further below in connection with the proposed concept or one or more examples (for example in connection with FIGS. 1 to 2 or FIGS. 4 to 6E).

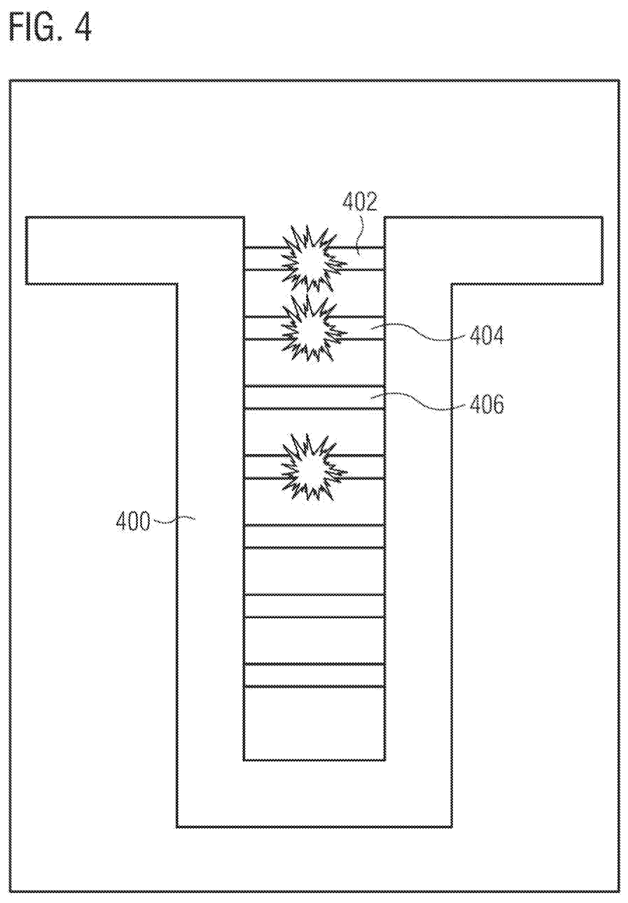

FIG. 4 shows a schematic illustration of one-time programmable structures that are severed using laser radiation. By way of example, a looped conductor track 400 can firstly be short-circuited by fuse structures 402, 404, 406. For setting an inductance value of the looped conductor track 400, by way of example, some of the fuse structures can be severed using a laser beam, illustrated schematically for the fuse structures 402, 404. With the use of laser beams for severing fuse structures, for example, no electrical structures can be arranged below the fuse structures 402, 404 on account of the risk of damage. Furthermore, by way of example, a width or height of metal connections forming the fuse structures may be restricted on account of a limitation of the laser power.

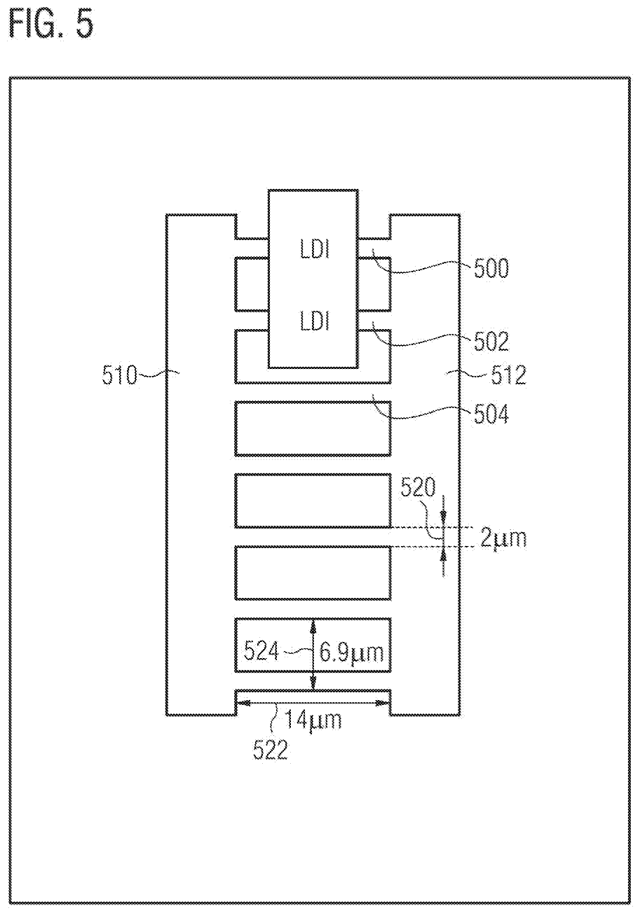

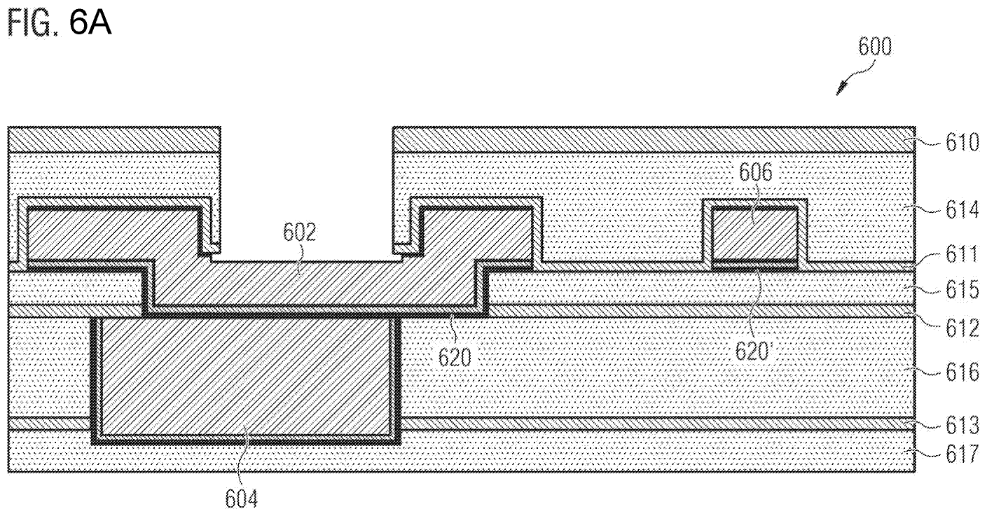

FIG. 5 shows a schematic illustration of one-time programmable structures that are severed using etching. Severing the one-time programmable structures using laser beams (for instance as shown in FIG. 4) can be replaced by the use of etching processes. By way of example, on the basis of test data, it is possible to generate a lithography pattern for an LDI apparatus. This pattern can be used for example to image a resist mask on the fuse structures or one-time programmable structures that are intended to be severed. By way of example, using this mask, it is possible to open the passivation above the fuse structures and aluminum layers and barrier layers can be separated.

FIG. 5 shows one-time programmable structures 500, 502, 504 that short-circuit two conductor tracks 510, 512. By way of example, the one-time programmable structures 500, 502 can be separated using etching processes, such that, instead of a short circuit, there is an open circuit between the conductor tracks 510, 512 at these locations after the etching. An etching mask can be produced using LDI in such a way that openings of the etching mask are arranged above separating regions of the one-time programmable structures 500, 502. The etching mask (not illustrated in FIG. 5) can have a common opening 530 above separating regions of adjacent one-time programmable structures.

By way of example, a width 520 of the one-time programmable structures can be 2 μm (or, for example, greater than 0.5 μm and/or less than 5 μm), a length 522 of the one-time programmable structures can be 14 μm (or, for example, greater than 5 μm and/or less than 40 μm) and/or a distance 524 between adjacent one-time programmable structures can be for example 6.9 μm (or, for example, greater than 2 μm and/or less than 20 μm).

Further details and aspects are described in connection with examples explained further above or further below. The examples shown in FIG. 5 can have one or more optional, additional features corresponding to one or more aspects described further above or further below in connection with the proposed concept or one or more examples (for example in connection with FIGS. 1 to 4 or FIGS. 6A to 6E).

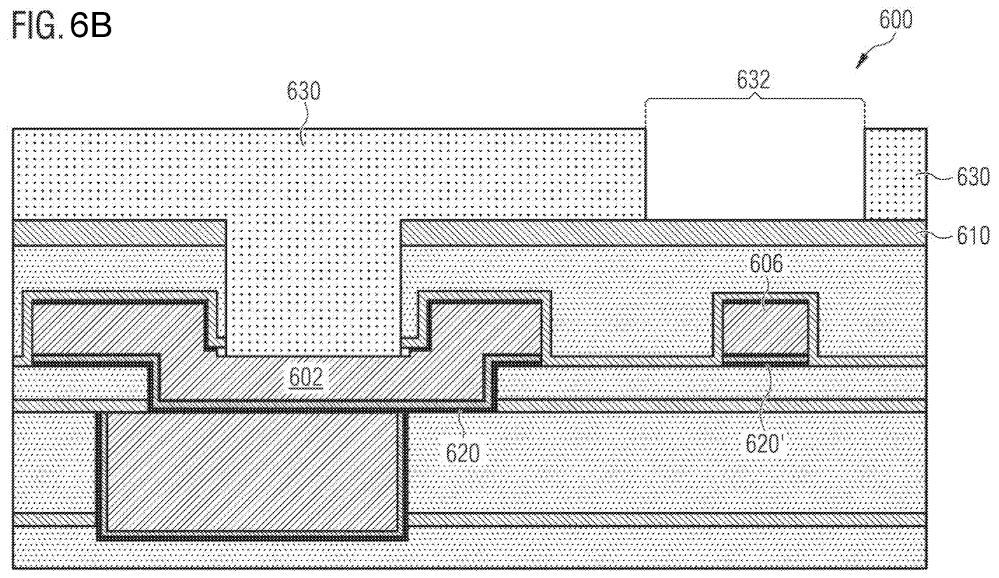

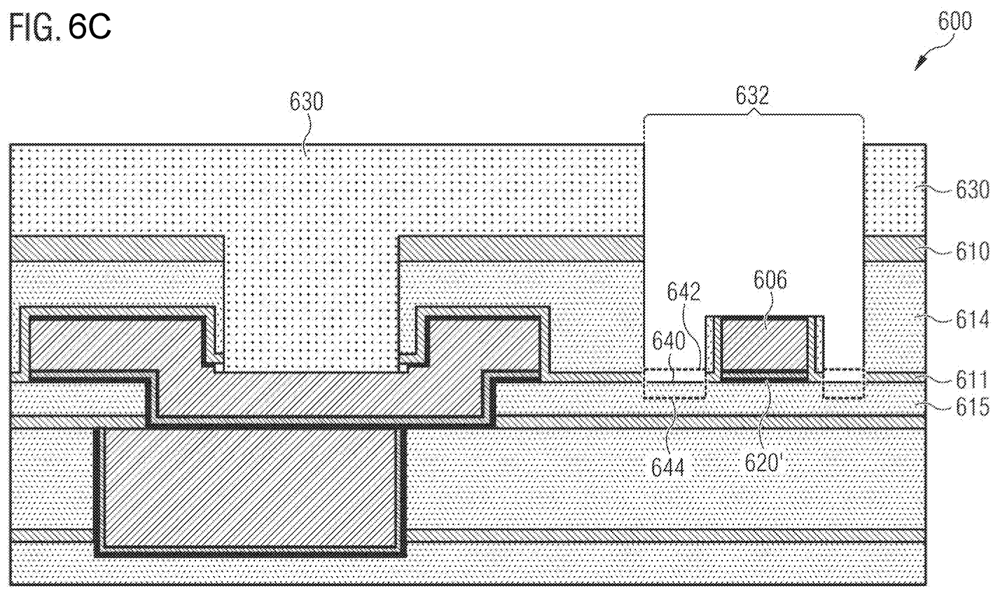

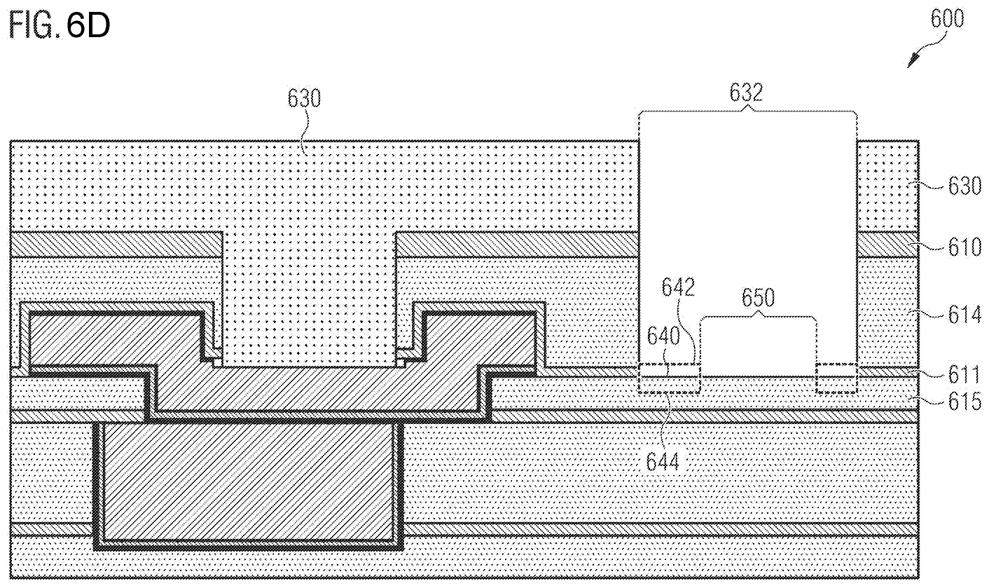

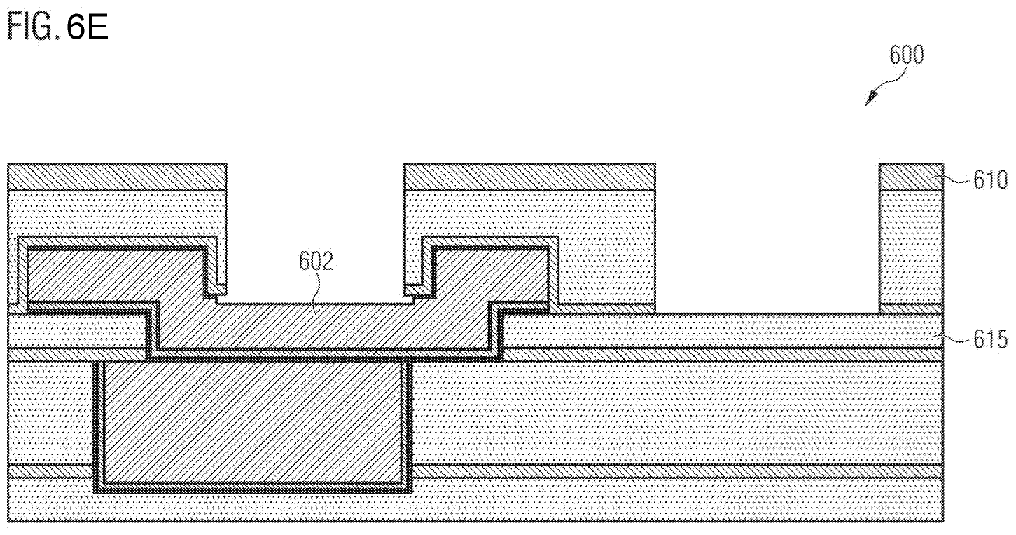

FIGS. 6A to 6E show a schematic illustration of a method for severing a one-time programmable structure using etching processes.

FIG. 6A shows a side view of a semiconductor component 600 having a plurality of metal structures 602, 604, 606; by way of example, the metal structure 604 can be formed by a copper layer. The metal structure 602 can comprise for example an uncovered pad structure for contacting an electrical circuit of the semiconductor component. An electrical property of the electrical circuit can be measured or tested via the pad structure. The metal structure 606 can provide a one-time programmable structure; by way of example, FIG. 6A shows a cross section within a separating region of the one-time programmable structure. By way of example, the metal layers 602 and 606 are comprised by one common, structured metal ply, for example composed of an aluminum-copper alloy. The metal layers of the semiconductor component are for example structured and insulated by passivation layers 610-617. By way of example, the passivation layers 610-613 comprise silicon nitride, and the passivation layers 614-617 comprise silicon oxide. A barrier layer 620 can be arranged between the metal layer 602 and the metal layer 604. The barrier layer 620 can comprise for example one or more of the following materials: tantalum (Ta), tantalum nitride (TaN), titanium (Ti), titanium nitride (TiN) and titanium-tungsten (TiW).

FIG. 6B shows the semiconductor component 600 having an applied resist layer 630. The resist layer 630 can cover for example the passivation layer 610 and also the pad structure of the metal structure 602. By way of example, the resist layer 630 can be exposed (for example using LDI) and developed in an opening region 632, such that the resist layer 630 is removed in the opening region 632. An opening of an etching mask formed by the resist layer can thus be provided above the one-time programmable structure 606.

FIG. 6C shows the semiconductor component 600 after a dry etching process of passivation layers. As a result of the etching, by way of example, the one-time programmable structure 606 can be uncovered. In this case, by way of example, it is possible to avoid spacers at the one-time programmable structure. As a result of the dry etching, the passivation layers 610, 614 and 611 can be removed in the opening region 632, such that a first surface 640 is uncovered alongside the one-time programmable structure 606, said first surface lying for example at a level of a barrier layer 620′ below the one-time programmable structure 606. By way of example, etching can be effected as far as the passivation layer 615. Alternatively, etching can be effected only as far as a second surface 642, which lies for example above the first surface 640. In this case, for instance, the passivation layer 611 is not etched. In a further example, by contrast, overetching can take place, such that the passivation layer 615 is also etched within the opening region 632, such that a third surface 644 situated below the first surface 640 is uncovered. After the etching of the passivation, by way of example, the one-time programmable structure can be severed by material in the separating region (for instance an aluminum-copper alloy, AlCu) and a barrier layer adjoining the one-time programmable structure being etched (for example by dry etching).

FIG. 6D shows the semiconductor component 600 after the one-time programmable structure 606 and also the barrier layer 620′ below the one-time programmable structure 606 have been removed using etching. The semiconductor component 600 in FIG. 6D thus has a severed separating region 650 of the one-time programmable structure. By way of example, after the etching of the one-time programmable structure 606, a surface within the opening region 632 can be planar, for example corresponding to the first surface 640. Alternatively, the surface within the opening region 632 can be embodied in a trough-shaped fashion, for instance if the passivation layer was previously etched as far as the second surface 642. In a further example, the surface within the opening region 632 can have a plateau which lies within the separating region 650 and which is surrounded by troughs, for instance if the passivation was previously overetched.

FIG. 6E shows the semiconductor component 600 having the severed one-time programmable structure after the removal of the resist layer 630. Since no unevennesses or impurities have arisen at the surface of the semiconductor component 600 during severing using etching, it is then possible, for example, to apply a closed isolation layer, for example an imide layer, on the surface of the semiconductor component 600, that is to say for example on the surface of the passivation layer 610, the uncovered surface of the passivation layer 615 and the pad structure.

Separating one-time programmable structures may be for example a useful process step for the production of radar products in order to set the oscillation frequency of VCOs (VCO: voltage controlled oscillator) to an operation frequency. By way of example, the radar products can be designed such that initially the oscillation frequency is greater than the operation frequency. In a part of the VCO, it is possible to provide for example a conductor track loop or looped conductor track in a copper layer, which can be short-circuited for example by an array of aluminum lines within the loop. By cutting or dividing some of said aluminum lines, it is possible for example to set the inductance of this copper loop. As a result, for instance, the oscillation frequency can be set or adjusted. By way of example, the oscillation frequency can be reduced by severing some structures. Furthermore, by way of example, a tolerance range encompassing the oscillation frequency can be reduced by severing the one-time programmable structures. By way of example, technologies can utilize the severing of one-time programmable structures for chip identification.

Further details and aspects are described in connection with examples explained further above or further below. The examples shown in FIGS. 6A to 6E can have one or more optional, additional features corresponding to one or more aspects described further above or further below in connection with the proposed concept or one or more examples (for example in connection with FIGS. 1 to 5).

The severing of one-time programmable structures using etching can make possible for example alternatives with respect to the fine setting of electrical circuits. With the use of etching for severing the one-time programmable structures, it is possible for example to arrange electrical lines or electrical structures below the one-time programmable structures. Severing using etching can reduce for example limitations regarding the width and/or thickness of the one-time programmable structures. Since, by way of example, in contrast to severing using laser beams, no impurities (spatter) arise on account of the separating process, it may be possible to apply an imide passivation on the severed one-time programmable structures.

Aspects of the disclosure relate to fuse cutting using lithographic means. One aspect relates for example to the use of known photolithographic processes and etching processes for cutting the fuses, for instance one-time programmable structures. This may be possible since flexible exposure apparatuses having sufficient resolution (for example <2 μm) and overlay accuracy (for example <0.5 μm) are available which can enable wafer-specific layouts to be exposed. In particular maskless wafer exposure, for example based on parallel laser beams, can offer a better throughput than electron beam processes, for example.

Further aspects relate for example to the production of fuses in electrical circuits. Fuses can be structures in a circuit which can be destroyed after production, for example using an electrical pulse or a laser pulse. In this way, fuses can be used for instance to tune electrical characteristics of circuits to target values. In some applications (for example products in the automotive field), fuses can be used to identify for example individual chips by generating unique chip codes that can be read out electrically or optically.

Some methods carry out the interruption of specific metal lines using a laser beam. This is, for example, a specialized and complex process that may use specialized technical apparatuses. Dividing metal lines using a laser pulse may cause for example undesired damage to the electrical circuits. For example, the use of highly doped substrates or the positioning of buried layers below laser fuses (for example one-time programmable structures to be severed using a laser beam) may be useful since the laser pulse can be absorbed by such layers. For example, damage to the substrate and subsequently cracks in the dielectric layers on the chip may occur. For the same reason, a positioning of electrical devices or wiring of metal lines below laser fuses may not be possible, for example, which results for instance in an increase in the chip size. Furthermore, for applications such as the adaptation of the oscillation frequency of voltage controlled oscillators (VCOs) e.g. in automotive radars, the use of fuses having a very low resistance value may be an important requirement. Therefore, the use of relatively thick and wide metal lines for the fuses may be useful. However, this would require higher power levels for the laser pulses in order to separate the fuses, and would thus increase the risk of damage to underlying layers. Methods for etching through fuse structures or one-time programmable structures are therefore proposed.

By way of example, the process of separating fuses using a laser beam can be replaced by a lithography process that allows the writing of exposure structures that can be adapted individually for each chip on the wafer. Such lithography processes are for example LDI (Laser Direct Imaging) or electron beam lithography. After this lithography step, for example, separating the fuses is carried out using dry or wet etching techniques. In this way, for example, damage to the substrate or metal spatter that may arise during the laser cutting process is avoided. In addition thereto, a positioning of wiring or devices below the fuses may be possible. Separating the fuses has for example far less strict limitations regarding the width or thickness of the metal lines used. Therefore, for example, RF-critical parts of the circuit that require low resistance values of the fuses can also be provided.

Furthermore, by virtue of the process proposed, in the case of a polyimide passivation layer, for instance, it may be possible for the imide layer to be deposited after fuse cutting. This is not possible in other processes, for example, on account of residues caused by laser ablation redeposition, for example, which would drastically weaken the imide adhesion around the fuses. In other processes, for example, imide is implemented before fuse cutting, thus necessitating an opening in the imide above the fuses. The proposed lithographic process can offer for example a closed imide passivation and therefore an improved reliability.

One example comprises an integrated circuit having n metal layers. The production of the fuse is carried out in the last metal layer, for example, which is also used as a connection pad metallization layer. After the structuring of this layer, the passivation layers comprising silicon oxide and silicon nitride can be deposited. Afterward, for example, the dielectric layers are removed above the bond connection pads in order to enable testing and bonding of the chips. For example, write structures for the LDI or electron beam lithography apparatuses are produced on the basis of the electrical test results. After coating the wafer with resist, it is possible to use the write structure to uncover the resist in regions where fuses are intended to be separated. After the resist has been developed, for example, the passivation layers on the fuses are etched away. In a second etching step, the metal lines can be separated by a standard dry or wet etching technique. As a final step, for example, the resist is removed.

Implementations of the proposed concepts are not limited to the last metal layer. By way of example, any of the metal layers can be used, for instance if a suitable etching process can be used to remove the dielectric layers on the metal line that is intended to be separated.

By way of example, by virtue of the proposed concept, an appearance of the fuses can change and connection pads and electrical behavior can remain the same. In the case of a polyimide passivation layer, it is possible to close the opening of the imide above the fuse region and for example special caution in applications with regard to an imide opening would not be necessary, for instance.

Adapting circuits on the basis of electrical test results may be useful for radar products. Providing an alternative process to laser cutting processes may be useful. Visual inspection of semiconductor chips makes it possible for example to differentiate whether laser cutting was employed to separate the chips (or fuses of the chips) or whether etching techniques were used for separating metal lines.

There may be for instance a development of an LDI system with sufficient resolution for this application. The use of this apparatus for adapting circuits on the basis of electrical results and individual chip marking is used for example in products on the automotive radar market. Other product segments, too, such as gesture detection, for example, can use these fine setting (trimming) techniques.

One example concerns the local provision of metal wet-etching liquids by inkjet printing for example only to those fuses that are intended to be etched. Since inkjet droplets may have a diameter of the order of magnitude of 20 to 50 μm, a required distance between fuse lines may be large.

The aspects and features that have been described together with one or more of the examples and figures described in detail above can also be combined with one or more of the other examples in order to replace an identical feature of the other example or in order additionally to introduce the feature into the other example.

The description and drawings present only the principles of the disclosure. Furthermore, all examples mentioned here are intended to be used expressly only for illustrative purposes, in principle, in order to assist the reader in understanding the principles of the disclosure and the concepts contributed by the inventor(s) for further development of the art. All statements herein regarding principles, aspects and examples of the disclosure and also concrete examples thereof encompass the counterparts thereof.

A block diagram can illustrate for example a rough circuit diagram which implements the principles of the disclosure. In a similar manner, a flow diagram, a flow chart, a state transition diagram, a pseudo-code and the like can represent various processes, operations or steps which are represented for example substantially in a computer-readable medium and are thus performed by a computer or processor, regardless of whether such a computer or processor is explicitly shown. Methods disclosed in the description or in the patent claims can be implemented by a component having a means for performing each of the respective steps of said methods.

It goes without saying that the disclosure of a plurality of steps, processes, operations or functions disclosed in the description or the claims should not be interpreted as being in the specific order, unless this is explicitly or implicitly indicated otherwise, for example for technical reasons. The disclosure of a plurality of steps or functions therefore does not limit them to a specific order unless said steps or functions are not interchangeable for technical reasons. Furthermore, in some examples, an individual step, function, process or operation can include a plurality of partial steps, functions, processes or operations and/or be subdivided into them. Such partial steps can be included and be part of the disclosure of said individual step, provided that they are not explicitly excluded.

Furthermore, the claims that follow are hereby incorporated in the detailed description, where each claim can be representative of a separate example by itself. While each claim can be representative of a separate example by itself, it should be taken into consideration that—although a dependent claim can refer in the claims to a specific combination with one or more other claims—other examples can also encompass a combination of the dependent claim with the subject matter of any other dependent or independent claim. Such combinations are explicitly proposed here, provided that no indication is given that a specific combination is not intended. Furthermore, features of a claim are also intended to be included for any other independent claim, even if this claim is not made directly dependent on the independent claim.

1. A method for programming a one-time programmable structure, the method comprising:
producing an electrical circuit having the one-time programmable structure; and
severing the one-time programmable structure by etching the one-time programmable structure in a separating region,
wherein an electrical property of the electrical circuit or a readable chip identification number is altered by severing the one-time programmable structure,
wherein the electrical property is a value of an inductance of the electrical circuit.

2. The method as claimed in claim 1, further comprising:
producing an etching mask after producing the one-time programmable structure, wherein the etching mask has an opening above the separating region of the one-time programmable structure.

3. The method as claimed in claim 2,
wherein the etching mask is produced using a maskless lithography method.

4. The method as claimed in claim 1,
wherein the etching for severing the one-time programmable structure comprises selectively applying an etching liquid above the separating region of the one-time programmable structure in a maskless fashion.

5. The method as claimed in claim 1,
wherein an isolation layer is applied after the etching in the separating region of the one-time programmable structure.

6. The method as claimed in claim 1,
wherein the one-time programmable structure is a conductor track which is severed.

7. The method as claimed in claim 1,
wherein the one-time programmable structure has a thickness of at least 0.7 μm within the separating region before the etching.

8. The method as claimed in claim 1,
wherein the one-time programmable structure has a width of at least 0.5 μm and less than 50 μm within the separating region before the etching.

9. The method as claimed in claim 1, further comprising:
etching a passivation layer arranged above the one-time programmable structure, such that the one-time programmable structure is exposed for the severing.

10. The method as claimed in claim 1, further comprising:
measuring an electrical parameter of the electrical circuit before severing the one-time programmable structure.

11. (canceled)

12. (canceled)

13. The method as claimed in claim 10,
wherein the electrical circuit has a plurality of one-time programmable structures, wherein at least one one-time programmable structure of the plurality of one-time programmable structures is separated based on the electrical parameter.

14. A semiconductor component comprising:
an electrical circuit; and
a severed one-time programmable structure of the electrical circuit,
wherein a separating surface of the one-time programmable structure is an etched surface,
wherein the electrical circuit has an oscillator circuit,
wherein the oscillator circuit is designed to generate an oscillator signal having a frequency that is set at least by the one-time programmable structure.

15. The semiconductor component as claimed in claim 14,
wherein an insulating layer arranged below the one-time programmable structure has a trench or a mesa in an etched separating region of the one-time programmable structure.

16. The semiconductor component as claimed in claim 14, further comprising:
an isolation layer arranged at least in a separating region of the one-time programmable structure.

17. The semiconductor component as claimed in claim 14,
wherein at least one part of the electrical circuit is arranged vertically between the one-time programmable structure and a semiconductor substrate of the semiconductor component.

18. The semiconductor component as claimed in claim 14,
wherein the electrical circuit is designed to detect whether the one-time programmable structure is severed.

19. (canceled)

20. A radio-frequency component comprising a semiconductor component as claimed in claim 14,
wherein the radio-frequency component is designed to emit a radio-frequency signal based on the oscillator signal.

21. The semiconductor component as claimed in claim 14,
wherein the electrical circuit has a plurality of one-time programmable structures, wherein at least one one-time programmable structure of the plurality of one-time programmable structures is separated based on an electrical parameter of the electrical circuit.

22. The semiconductor component as claimed in claim 14, further comprising:
an etching mask that has an opening above the separating surface of the one-time programmable structure.

23. The semiconductor component as claimed in claim 14, further comprising:
a passivation layer arranged above the one-time programmable structure, such that the one-time programmable structure is exposed for severing.
